(19) United States
(12) Patent Application Publication
(10) Pub. No.: US 2026/0036619 A1
(43) Pub. Date: Feb. 5, 2026

(54) TEST AND/OR MEASUREMENT INSTRUMENT, METHOD FOR PROCESSING AN ELECTRICAL SIGNAL, AND COMPUTER-IMPLEMENTED METHOD FOR TRAINING

(71) Applicant: Rohde & Schwarz GmbH & Co. KG, Muenchen (DE)

(72) Inventor: Wolfgang HERBORDT, Muenchen (DE)

(21) Appl. No.: 18/789,898

(22) Filed: Jul. 31, 2024

(51) Int. Cl. G01R 31/28

(52) U.S. Cl. CPC G01R 31/2846

(57) ABSTRACT

A test and/or measurement instrument includes a frontend having at least an input for receiving an electrical signal. The frontend also includes at least one processing circuit configured for processing the electrical signal, thereby generating a processed electrical signal. The test and/or measurement instrument further includes a backend connected with the frontend such that the backend receives the processed electrical signal. The backend includes at least one signal processing architecture based on artificial intelligence. The signal processing architecture based on artificial intelligence is configured for at least partially compensating signal distortions caused by the frontend when processing the electrical signal in order to generate the processed electrical signal. Further, a method for processing an electrical signal as well as a computer-implemented method for training a signal processing architecture are described.

### FIELD OF THE DISCLOSURE

Embodiments of the present disclosure generally relate to a test and/or measurement instrument for analyzing an electrical signal, a method for processing an electrical signal, and a computer-implemented method for training a signal processing architecture.

### BACKGROUND

The performance of frontends, such as analog frontends, of test and/or measurement instruments, e.g. oscilloscopes, analyzers or other instruments processing electrical signals, is typically limited by non-ideal frequency response characteristics regarding the magnitude and the phase. Commonly, these non-ideal frequency response characteristics cause signal distortions within the processed electrical signals which limit the achievable signal quality, namely the signal-to-noise ratio. The non-ideal frequency response characteristics may have their origin as to various reasons, such as non-ideal linear or non-linear behaviors of the signal processing path or cross-talk, e.g. interleave distortions in case of interleaved analog-to-digital converters (ADCs). In addition, environmental characteristics of the frontends may also have an influence on the signal processing, thereby leading to further distortions.

These unwanted effects on the processed signals are even further strengthened as the bandwidth of the analog frontends become larger. The larger the bandwidth is, the more difficult it is to design the frontend in a way that the frontend itself meets all the frequency response requirements.

To encounter the signal-influencing effects, one approach makes use of linear finite impulse response (FIR) filtering techniques to compensate for the linear effects. Furthermore, polyphase filters are known for compensating any interleaving distortions. For the non-linear effects, (FIR) filtering techniques are not applicable and, thus, Volterra filters or Wiener Hammerstein models have been applied.

Accordingly, for compensating different distortion types, such as linear and non-linear signal distortions, different filtering techniques have to be applied. In addition, in view of ever increasing bandwidths the achievable signal quality by these prior art filtering techniques is limited.

Hence, there is a need for a test and/or measurement instrument and a respective method capable of analyzing electrical signals, which enable an improved signal quality to be achieved even for large bandwidths and complex non-ideal frequency response scenarios. Preferably, the number of required filtering architectures can be reduced compared to prior art approaches even if different signal distortion types are to be compensated.

### SUMMARY

A summary of certain embodiments disclosed herein is set forth below. It should be understood that these aspects are presented merely to provide a brief summary of these embodiments and that these aspects are not intended to limit the scope of this disclosure. This disclosure may encompass a variety of aspects that may not be set forth below. Some aspects as explained in view of methods, others in view of devices. However, the respective aspects are to be correspondingly transferred from methods to devices and vice versa.

Embodiments of the present disclosure relate to a test and/or measurement instrument for analyzing an electrical signal. In an embodiment, the test and/or measurement instrument comprises a frontend having at least an input for receiving an electrical signal, e.g. a raw electrical signal not being pre-processed. The frontend also comprises at least one processing circuit configured for processing the electrical signal received, e.g. the raw electrical signal, thereby generating a processed electrical signal. The test and/or measurement instrument also comprises a (digital) backend connected with the frontend such that the backend receives the processed electrical signal. The backend comprises at least one signal processing architecture based on artificial intelligence. The signal processing architecture based on artificial intelligence is configured for at least partially compensating signal distortions caused by the frontend when processing the electrical signal received in order to generate the processed electrical signal.

Embodiments of the test and/or measurement instrument makes use of the finding that an artificial intelligence based signal processing architecture can be applied to compensate for any type and combination of signal distortions caused by the frontend. Thus, a single filtering architecture may be sufficient to compensate for different signal distortion types. This benefit is also achieved even if the bandwidth becomes larger. Hence, in view of increasing bandwidths, the performance of the test and/or measurement instrument disclosed herein will become more prominent as compared to previous approaches as the signal distortions may be efficiently compensated.

According to an aspect, one or more embodiments of the present disclosure relate to a method for processing an electrical signal. In an embodiment, the method comprises at least the steps of:
receiving an electrical signal by at least one input of a frontend of a test and/or measurement instrument,
processing the received electrical signal by at least one processing circuit of the frontend, thereby generating a processed electrical signal,
forwarding the processed electrical signal to a backend of the test and/or measurement instrument, and
compensating at least partially distortions caused by the frontend during processing of the received electrical signal by at least one signal processing architecture based on artificial intelligence.

The advantages achieved in view of the before mentioned test and/or measurement instrument are correspondingly achieved also in view of the method for processing an electrical signal. In essence, multiple different types of distortions may be compensated by the artificial intelligence based signal processing architecture such that the complexity is reduced, which also applies for the method for processing an electrical signal in a similar manner. In an embodiment, all distortions, e.g. also cross-talk effects, may be compensated using a single architecture. Hence, the signal processing is simplified as compared to known techniques.

The electrical signal received may be considered an electrical signal which is provided by or received from an external device, e.g. the (raw) electrical signal. For example, a sensor circuit may be used to sense the electrical signal. In some instances, the electrical signal may be obtained from a device, such as a device under test (DUT), for which the electrical properties shall be evaluated by the test and/or measurement instrument. In essence, the electrical signal received relates to an electrical signal which is to be processed by the test and/or measurement instrument to gain further insight into an external device like the DUT. In some examples, the test and/or measurement instrument itself may comprise the sensor circuit configured to sense the electrical signal.

Generally described, the processing circuit may be considered as a circuit configured to process the electrical signal received according to a specific processing routine. For example, the processing circuit may be configured to amplify, transform, or convert the electrical signal received according to a specific procedure, thereby generating the processed electrical signal. Hence, the processing circuit may be at least one of an amplifier or a signal converter, such as an analog-digital-converter (ADC). Of course, other types of processing circuits are considerable as well. In other words, the processed electrical signal may be an amplified electrical signal, a transformed electrical signal, or a converted electrical signal.

In an embodiment, the test and/or measurement instrument may comprise multiple separate processing circuits of a single type or of different types. In this aspect, the multiple processing circuits may be arranged subsequent to each other and may subsequently process the electrical signal. In this regard, the electrical signal can be considered raw only in view of the most upstream processing circuit while for the remaining processing circuits being arranged downstream of the upstream processing circuit, the electrical signal may be considered to already having been processed, i.e. being a processed electrical signal.

Alternatively, multiple processing circuits of the same or of different types may also be arranged in parallel to each other such that at least two processing circuits may receive the same or at least a corresponding electrical signal. This may be achieved by separate signal paths of the frontend.

In any case, the processing applied by the processing circuit(s) of the frontend leads to a processed electrical signal being output by the frontend. In addition, the processing of the electrical signal may generally cause signal distortions to the processed electrical signal. The specific distortions caused depend at least on the specific processing circuit, but may also depend on other influences, as will be explained in further detail below.

Generally described, the signal processing architecture based on artificial intelligence may be considered as an architecture receiving an input signal and providing an output signal. In an embodiment, the signal processing architecture based on artificial intelligence is characterized by internal parameters, such as a weight distribution (or feature map) which determine how the input signal is modified to achieve the output signal. In this regard, the signal processing architecture based on artificial intelligence is configured to assess which signal distortions to the electrical signal received the at least one processing circuit of the frontend causes when processing the electrical signal received.

In addition, the signal processing architecture may take properties and/or parameters of the at least one processing circuit into account to assess which signal distortions are caused. This enables to identify the distortions within the processed electrical signal such that compensation thereof is readily achievable.

In an embodiment, the signal processing architecture based on artificial intelligence is at least partially established in software running on a circuit and/or in hardware. Accordingly, multiple different implementations are generally possible such that the signal processing architecture can be adapted to the specific use case.

In some instances, the signal processing architecture based on artificial intelligence may be implemented using at least one of an application-specific integrated circuit (ASIC), a field programmable gate array (FPGA), and a central processing unit (CPU), which are specific circuits. Therefore, a wide variability of employable architectures is provided.

According to an alternative viewpoint, one may consider that the signal processing architecture based on artificial intelligence is configured to evaluate signal portions within the processed electrical signal which may be assumed to relate to signal distortions. Accordingly, the processed electrical signal having the signal distortions is at least partially corrected by cancelling out the respective distortions introduced when processing the electrical signal by the frontend, namely the at least one processing circuit.

As a consequence, an electrical signal is achieved for which the distortions caused by the frontend are at least partially compensated such that a high signal quality is obtained, e.g. for further processing. The distortions caused by the frontend may also be at least substantially compensated such that an (almost) optimized signal quality is obtained. In this aspect, any remaining signal distortions may be so small that they may be negligible and that they do not significantly influence the underlying electrical signal. In a specific case, the distortions caused by the frontend are fully compensated.

According to an aspect, the signal processing architecture based on artificial intelligence is based, for example, on machine learning or deep learning.

Generally described, machine learning capabilities enable the signal processing architecture to adapt itself during use so as to improve the signal processing behavior which is executed. For example, machine learning is based on statistics-based approaches for adapting the signal processing routine. Since the characteristics of the signal distortions which are included in the processed electrical signal cannot be analytically described, machine learning can be used to compensate the signal distortions. However, much information and statistical data exists or can be acquired to describe the actually arising distortions which are caused by the at least one processing circuit. In an embodiment, the machine learning also provides an adapting mechanism that is executed according to an automated approach.

Deep learning enables a sophisticated signal processing routine in that multiple subsequent individual processing events are executed. The subsequent individual processing events collectively establish a common signal processing routine. The common signal processing routine results in a collective processing that as to the individual sub-processing events is based on a broader basis regarding potential influences, thereby improving the overall quality of the outcome. Deep learning can be supervised, semi-supervised or unsupervised. For example, unsupervised deep learning routines provide the possibility of reducing the operational expenses required for optimizing the signal processing making behavior of the signal processing architecture based on artificial intelligence.

In an embodiment, the signal processing architecture based on artificial intelligence comprises an artificial neural network (ANN). While artificial intelligence can also be employed by architectures not being based on artificial neural networks, such as rules-based architectures, artificial neural networks provide an improved variability and adaptability in view of the underlying function. Put differently, artificial neural networks can be precisely tuned in view of the functionality they serve. In addition, sophisticated techniques such as machine learning and deep learning can be efficiently implemented in artificial neural networks. For example, deep learning capabilities can be provided by setting up the artificial neural network to comprise at least two subsequent hidden layers comprising individual artificial neurons (also called nodes) of the network.

In general, a layer of the artificial neural network is considered to be hidden if it is arranged between an input layer and an output layer of the artificial neural network. In this regard, the input layer receives an input signal provided to the artificial neural network, namely the processed electrical signal, and the output layer provides an output signal of the artificial neural network, namely an at least partially compensated electrical signal, for example the (fully) compensated electrical signal.

In an embodiment, the signal processing architecture based on artificial intelligence may comprise at least one layer. Generally, the signal processing architecture based on artificial intelligence may have several layers. Each layer comprises at least one neuron, and in general multiple neurons of the network. Each neuron is coupled to at least one or multiple preceding neurons and at least one or multiple subsequent neurons. For each neuron, a weight of the probabilities of particular signal processing processes corresponding to specific neuron connections is determined, for instance by a kernel (function). Where each neuron receives at least one (or multiple) respective input signals from one (or multiple) preceding neurons, it also outputs at least one (or multiple) respective output signals to one (or multiple) subsequent neurons. The weight of a specific neuron describes the relative probabilities of the respective neuron connections within the network. The overall performance of the signal processing architecture based on artificial intelligence results in a combination of all weights assigned to the different neurons. In this regard, a layer can be contemplated a specific plane within the overall signal processing process provided by the signal processing architecture.

According to a further aspect, the underlying functional principle of the artificial neural network having a layer is based, for example, on an applied optimization scheme. In particular, the artificial neural network can be trained based on an adapted training method to execute an optimization scheme. This aspect will be described later in more detail.

In an embodiment, a number of layers of the signal processing architecture based on artificial intelligence depends on the number of processing circuits of the frontend. For example, the number of layers of the signal processing architecture may be such that the signal processing architecture at least comprises a number of hidden layers being same with the number of processing circuits of the frontend. Accordingly, an individual hidden layer may be assigned to a specific processing circuit so as to at least partially compensate the signal distortions caused by the specific processing circuit.

In an embodiment, the number of layers of the signal processing architecture may however also be larger than the number of processing circuits of the frontend. In this scenario, multiple different layers may be assigned to collectively compensate at least partially the signal distortions caused by a specific processing circuit of the frontend.

In embodiments where the signal processing architecture based on artificial intelligence comprises an artificial neural network, the artificial neural network may comprise at least one convolutional layer having at least one kernel. The kernel may be considered a neuron that applies a kernel function on an input signal, e.g. an input vector, for which the weight distribution is adaptable, for example in an automated self-adapting fashion during the course of a training method.

According to earlier approaches of artificial neural networks, the neurons were fully connected. A fully connected neuron of a specific layer of the network is a neuron that is coupled to all neurons of a preceding and a subsequent layer.

A kernel comprises a feature map, also sometimes called an activation map, which describes the relation between a received input signal and a provided output signal. In other words, a kernel in an artificial neural network relates to a set of learnable weights and biases that are applied to the input data during a convolution operation.

According to some nomenclatures each kernel of a convolutional layer is considered as an individual filter. However, other nomenclatures assign the overall entirety of all kernels that provide a common functionality a convolutional filter. The latter nomenclature will be used hereinafter.

In an embodiment, the signal processing architecture based on artificial intelligence is configured to convolute the processed electrical signal with at least one kernel and to provide an output signal. In this regard, the kernel applies the respective feature map to determine the respective output signal based on the received processed electrical signal. For example, the kernel may be set in course of the training such that signal distortions included within the processed electrical signal are at least partially compensated as a result of the processing via the kernel.

In an embodiment, each kernel may contribute to a specific filter length. The filter length describes the dimensions of the feature map of the respective kernels associated with the filter. Since a specific kernel may be coupled to several preceding nodes or other kernels and to several subsequent nodes or kernels, the feature map generally corresponds to a matrix having respective entries in view of all possible connections via the respective kernel.

The collection of all kernels enable a specific signal processing to be employed such as a filtering function. Mathematically the signal processing can be considered a tensor comprising the individual matrices assigned to the various kernels.

In an embodiment, a kernel of a convolutional layer is set such that the kernel applies a non-linear activation function to the output signal of the respective layer, such as the sigmoid function, the softmax function, or a rectified linear unit (also called ReLU). This enables non-linear responses to be obtained by each kernel. Therefore, a greater variability of the output signal is provided, also enabling to modify the processed electrical signal according to a non-linear manner. In an embodiment, in view of the wanted compensation of signal distortions, non-linear signal distortions can be at least partially compensated by making use of non-linear functions employed by the kernel.

In an embodiment, the convolutional layer having at least one kernel is configured to at least partially compensate signal distortions caused by at least one analog processing device of the frontend. Analog devices usually cause non-linear effects and distortions while processing electrical signals. As to the characteristics of the convolutional layer described herein before, these non-linear effects can be efficiently compensated.

In an embodiment where the signal processing architecture based on artificial intelligence comprises an artificial neural network, a number of convolutional layers having kernels may depend on the number of processing circuits of the frontend. That is, different convolutional layers may be regarded to compensate signal distortions caused by different components of the frontend. For example, at least one or multiple convolutional layers may be regarded (and assigned) so as to at least partially compensate signal distortions caused by a specific single processing circuit of the frontend.

In an embodiment, the signal processing architecture based on artificial intelligence comprises at least two cascaded layers, wherein one of the cascaded layers is an output layer that outputs an output signal with at least partially compensated signal distortions. The output layer may be regarded a result layer of the procedure executed by the signal processing architecture. Therefore, the processing by the signal processing architecture results in an output signal which is provided to other components using the output layer.

In an embodiment, the output signal provided by the output layer may be such that for the output signal component-specific signal distortions caused by the frontend are at least partially compensated. Here, the component-specific signal distortions refer to distortions caused by a specific processing circuit of the frontend. In other words, the at least two cascaded layers of the signal processing architecture based on artificial intelligence may be set up and trained such that at least the signal distortions caused by a specific processing circuit of the frontend can be at least partially compensated, for example fully compensated. Of course, the signal processing architecture may comprise additional layers such that for each processing circuit of the frontend the respective component specific signal distortions can be at least partially compensated when providing the output signal through the output layer.

In an embodiment, the output layer may be a fully connected layer. This means that the one or multiple neurons of the output layer are coupled to all neurons (or kernels) of the layer preceding the output layer.

In an embodiment, an input layer of the signal processing architecture may be a fully connected layer. This means that the one or multiple neurons of the input layer are coupled to all neurons (or kernels) of the layer subsequent to the input layer.

In an embodiment, the at least one signal processing architecture based on artificial intelligence may be configured to at least compensate linear and/or non-linear signal distortions caused by the frontend. For compensating non-linear signal distortions, for example, convolutional layers having kernels which are associated with non-linear functions, can be applied. Of course, convolutional layers can also be applied to compensate for linear signal distortions. However, the compensation of linear signal distortions may also be achieved based on classical layers of an artificial neural network, such as hidden layers or hidden layers enabling deep learning capabilities (i.e. cascaded hidden layers).

Another aspect provides that at least one processing circuit of the frontend is configured, for example, to perform a standardization of the electrical signal. Accordingly, a reference value, for instance a mean value, of the electrical signal may be shifted while rescaling the electrical signal accordingly. The respective value may relate to frequency and/or amplitude.

In an embodiment, the standardization of the electrical signal may be applied by a processing circuit of the frontend.

Alternatively or cumulatively, the standardization or an additional standardization may also be employed by an architecture of the backend, but prior to the signal processing architecture based on artificial intelligence.

In an embodiment, the test and/or measurement instrument comprises a post-processing circuit configured to remove a standardization from the output signal. Here, the output signal may refer to the output signal provided by the signal processing architecture based on artificial intelligence. Therefore, the effects caused by the standardization procedure applied previously can be compensated. In this regard, the post-processing circuit may be coupled to the at least one processing circuit configured to perform the standardization of the electrical signal. For example, the post-processing circuit may receive a reference signal which is used when compensating for the standardization of the electrical signal caused before.

In an embodiment, the post-processing circuit configured to remove the standardization from the output signal is arranged downstream of the at least one signal processing architecture based on artificial intelligence.

Alternatively, the post-processing circuit may be established based on an artificial neural network being arranged downstream of the signal processing architecture based on artificial intelligence.

Put differently, while the signal processing architecture based on artificial intelligence is usable to at least partially compensate for signal distortions caused by the frontend, subsequent to this compensation procedure, also a standardization applied within the frontend can be compensated within the backend.

In an embodiment, the at least one signal processing architecture based on artificial intelligence is configured to at least partially compensate signal distortions introduced by the frontend in real-time. This means that the time period required for compensating signal distortions caused by the frontend may correspond to or may be shorter than a sampling time of the frontend. Hence, the signal processing speed of the test and/or measurement instrument is high.

In an embodiment, the test and/or measurement instrument comprises an acquisition memory for storing at least partially compensated electrical signals. In this case, the acquisition memory is arranged downstream of the at least one signal processing architecture based on artificial intelligence. Here, (at least partially) compensated electrical signals refer to output signals of the signal processing architecture based on artificial intelligence. Put differently, the (at least partially) compensated electrical signals refer to electrical signals for which the signal distortions caused by the frontend are (at least partially) compensated.

Alternatively or cumulatively, the signal processing architecture based on artificial intelligence may also comprise multiple artificial neural networks. In this case, the acquisition memory may also be arranged between two of the multiple artificial neural networks. Hence, according the to this scenario, the acquisition memory is configured to store partially compensated electrical signals of the backend, i.e. electrical signals which do not represent the final output signals, e.g. the fully compensated signals, of the signal processing architecture based on artificial intelligence. In this regard, a first artificial neural network preceding the acquisition memory may be applied to at least partially compensate the processed electrical signal, e.g. for specific types of signal distortions caused by the frontend. In addition, another artificial neural network being arranged subsequent to the respective acquisition memory may be applied to compensate further, e.g. for different types of signal distortions caused by the frontend.

In an embodiment, the test and/or measurement instrument comprises an acquisition memory for storing processed electrical signals. In this scenario, the acquisition memory is configured to provide the processed electrical signals to the at least one signal processing architecture based on artificial intelligence. In this case, the acquisition memory is arranged upstream of the at least one signal processing architecture based on artificial intelligence. Also, in this case the at least one signal processing architecture based on artificial intelligence is configured to at least partially compensate signal distortions in non-real-time based on the received processed electrical signals, but in course of a post-processing. This enables an intermediate storing of the processed electrical signals. Accordingly, as to the intermediate storing, additional time can be used when applying the signal processing architecture based on artificial intelligence for at least partially compensating the signal distortions caused by the frontend. As to the additional time available, the precision and quality of the compensating technique executed by the signal processing architecture may be improved.

In an embodiment, the at least one signal processing architecture based on artificial intelligence is coupled to or comprises at least one of an electrical linear filter, a Volterra filter, or a non-linear filter. For example, the filtering functionalities of the respective filters can be employed by the signal processing architecture in case the architecture comprises an artificial neural network. Put differently, the filtering functionality of the respective filter types are mimicked by the signal processing architecture based on artificial intelligence. Hence, an architecture is provided which enables to efficiently compensate linear and non-linear signal distortions.

In an embodiment, the test and/or measurement instrument may comprise at least two signal paths for processing electrical signals, which are provided outside the signal processing architecture. For example, the at least two signal paths may be arranged in parallel to each other. Based on the multiple signal paths, higher sampling rates and larger bandwidths during processing of the electrical signals may be achievable. In particular, the multiple signal paths may be provided within the frontend.

In an embodiment, the electrical signals resulting from the multiple signal paths may be combined with each other again before a single processed electrical signal of the frontend is provided to the backend.

Alternatively, the backend may comprise parallel signal processing architectures to be applied for each of the processed electrical signals of separate signal paths of the frontend.

In some examples, multiple signal paths may be applied to establish interleaved processing circuits, e.g. by means of interleaved parallel ADCs. Linear and non-linear signal distortions caused by these configurations lead to a reduction of the spurious-free dynamic range. In this regard, at least one convolutional layer of the signal processing architecture based on artificial intelligence may be adapted to map the behavior of the explained interleaved parallel ADCs such that the signal distortions caused thereby are at least partially compensated.

In an embodiment, the at least one signal processing architecture based on artificial intelligence is configured to take at least one configuration parameter and/or at least one environmental parameter of the frontend into account. The at least one configuration parameter, e.g. the setting of the test and/or measurement instrument, and/or at least one environmental parameter influences the distortions caused by the frontend during processing the electrical signal received. In general, configuration parameters and environmental parameters can influence the behavior of processing circuits as to how signal distortions are caused.

Here, configuration parameters, namely the setting of the test and/or measurement instrument, refer to parameters influencing the functionality of the processing circuit of the frontend itself. As an example, in case the processing circuit relates to an amplifier, a gain set may influence the signal distortions caused to the electrical signal being processed. Other settings like an offset may also influence the signal distortion.

Environmental parameters relate to environmental properties, such as for example a temperature or humidity, which also influence the signal distortions. For instance, higher temperatures cause a thermal drift, e.g. in amplifiers, resulting in a different distortion.

Hence, by considering the at least one configuration parameter and/or the at least one environmental parameter, the respective occurring signal distortions can be compensated by the signal processing architecture based on artificial intelligence with improved precision. In other words, an improved compensating effect is achieved.

In an embodiment, the signal processing architecture based on artificial intelligence may be coupled to an external environmental sensing device providing information with regard to the at least one environmental parameter. Alternatively, the test and/or measurement instrument comprises an environmental sensor for sensing the respective environmental parameter, e.g. a temperature sensor and/or a humidity sensor.

Generally, the test and/or measurement instrument as well as the method for processing an electrical signal described above provide a reduced computational complexity for the backend, e.g. the digital backend, compared to conventional approaches like Volterra filters and, by that, increased likelihood of compensating linear as well as nonlinear distortions in the signal processing path, for example the real-time signal processing path.

Consequently, signals with larger bandwidth can be compensated appropriately, e.g. signals with a bandwidth of 8 GHz or even higher.

In an embodiment, the signal processing architecture based on artificial intelligence may be located within the backend of the test and/or measurement instrument, for instance between the frontend and the acquisition memory provided in the backend such that the processed electrical signal received from the front end is compensated before being acquired. In other words, the signal processing architecture based on artificial intelligence is located in the real-time signal processing path, thereby ensuring real-time compensation. However, the signal processing architecture based on artificial intelligence may also be provided in the post-processing part of the backend, e.g. after the acquisition memory. Alternatively, the signal processing architecture based on artificial intelligence is split into at least two portions that are located before the acquisition memory and after the acquisition memory, e.g. in the real-time portion and the post-processing portion of the backend, thereby optimizing the overall distortion compensation.

According to another aspect, the present disclosure also relates to a computer-implemented method for training a signal processing architecture based on artificial intelligence to at least partially compensate distortions of electrical signals introduced by a frontend of a test and/or measurement instrument. The signal processing architecture based on artificial intelligence is trained by a training data set such that the signal processing architecture based on artificial intelligence is configured to at least partially compensate the distortions introduced by the frontend of the test and/or measurement instrument when processing the electrical signal. The training data set encompasses input data associated with the electrical signal received by the frontend and training data associated with an electrical signal processed by the frontend of the test and/or measurement instrument. The signal processing architecture based on artificial intelligence is fed with the training data such that the signal processing architecture based on artificial intelligence processes the training data in order to output compensated data associated with an at least partially compensated electrical signal. The compensated data is compared with the input data encompassed in the training data set in order to determine a deviation between the input data and the compensated data outputted by the signal processing architecture based on artificial intelligence. The signal processing architecture based on artificial intelligence is adapted when a deviation between the input data and the compensated data occurs that is higher than a pre-defined threshold value. The respective deviation between the input data and the compensated data may also be regarded as error since the occurrence of no deviation means that the compensated data exactly correspond to the input data, e.g. the electrical signal without any distortions introduced. The method for training may take place during production of the test and/or measurement instrument.

In an embodiment, the computer-implemented method may in particular be configured to prepare the signal processing architecture for being used in the test and/or measurement instrument or the method for processing an electrical signal, which are described before. In other words, the signal processing architecture based on artificial intelligence may be trained based on the computer-implemented method for training described above.

Consequently, the test and/or measurement instrument or the method for processing an electrical signal make use of a signal processing architecture based on a trained artificial intelligence.

In some examples, a gradient-based optimization scheme is applied when comparing the compensated data outputted by the signal processing architecture based on artificial intelligence with the input data encompassed in the training data set. For example, the gradient can be determined using a backpropagation algorithm employed by the signal processing architecture based on artificial intelligence. In essence, the gradient optimization scheme relates to a first-order iterative algorithm for finding a local minimum, namely the local minimum of the deviation/error between the input data and the compensated data.

Alternatively, a minimization of an error (error minimization scheme), such as the mean square error, is applied when comparing the compensated data outputted by the signal processing architecture based on artificial intelligence with the input data encompassed in the training data set. This can be considered a procedure where the compensated data associated with different electrical signals, namely different output signals of the signal processing architecture based on artificial intelligence, is determined such that a mean of several individual compensations done by the signal processing architecture based on artificial intelligence is minimized. Put differently, the signal processing architecture based on artificial intelligence processes data associated with several processed electrical signals of the frontend, thereby outputting data associated with several respective compensated signals. The respective errors/deviations of the several compensated signals compared to corresponding input data, e.g. received electrical signals, are determined, wherein a mean of these errors/deviations is used for the optimization, e.g. the minimization.

In an embodiment, the training data set is obtained from a series of measurements and/or from simulations. Hence, real measurements may be performed in order to obtain the training data indicative of the electrical signal processed by the frontend while knowing the input signal processed by the frontend, namely the electrical signal received. Alternatively, the training data may be obtained from simulations of the signal processing chain within the frontend. In addition, the training data set may comprise data obtained from measurements which are enriched by simulated data. In one example, a known electrical signal may be processed by the frontend to achieve the processed electrical signal. The processed electrical signal may then be input to the signal processing architecture based on artificial intelligence for training purposes.

Depending on the intrinsic parameters of the signal processing architecture based on artificial intelligence, such as for example depending on the feature maps of kernels or the weights applied, the processed electrical signal will be modified by the signal processing architecture in an embodiment based on artificial intelligence with the goal of obtaining the at least partially compensated electrical signal, for which the signal distortions caused by the processing using the at least one processing circuit of the frontend, are at least partially compensated. Naturally, when initially employing the signal processing architecture based on artificial intelligence the intrinsic parameters thereof are not yet optimized. Therefore, the compensated signal can be compared to the initial electrical signal inputted into the frontend, namely the known electrical signal. As indicated above, the input data indicative of the input signal, namely the known electrical signal, may be used which is part of the training data set. Based on the comparison, conclusions can be made as to how the parameters of the signal processing architecture based on artificial intelligence are to be adapted in order to improve the correlation between the electrical signal and the at least partially compensated electrical signal.

As mentioned herein before, the adjustment of the intrinsic parameters of the signal processing architecture based on artificial intelligence can be made according to an automated fashion, i.e. based on machine learning or deep learning.

In an embodiment, the technique of providing the electrical signals and comparing the outcome of the signal processing architecture based on artificial intelligence, i.e. the at least partially compensated signal, with the respectively underlying electrical signals may be repeated several times in order to adjust the intrinsic parameters of the signal processing architecture based on artificial intelligence further, and in order to ultimately optimize these parameters based on the optimization scheme. In this regard, an entire set of electrical signals can be provided within the course of the computer-implemented method for training the signal processing architecture based on artificial intelligence.

In an embodiment, the computer implemented method for training the signal processing architecture based on artificial intelligence may be extended in view of the optimization scheme applied.

For instance, according to an example, a momentum can be artificially added to the processed electrical signal before the processed electrical signal is provided to the signal processing architecture. In this regard, the momentum is used to accelerate the convergence of the optimization such that the local minimum is obtained earlier. In case of loss landscape, the momentum ensures that flat parts of the loss landscape are reached earlier.

According to a different example, the optimization may also be extended by applying adaptive learning rates. In other words, the adjustment steps applied when adjusting the intrinsic parameters of the signal processing architecture based on artificial intelligence may be varied depending on the comparison described before. For example, the deviation/error determined in view of the comparison of the compensated electrical signal with the electrical signal may be used to adapt the learning rate. In some cases, if high deviations/errors are determined to be present, comparatively high learning rates may be applied leading to rather large adjustments of the intrinsic parameters of the signal processing architecture. In contrast, if rather small deviations/errors are determined to be present, the learning rates may be reduced as compared to the before scenario.

According to another example, the signal processing architecture based on artificial intelligence may also be provided with initializing parameters. For example, the initializing parameters may relate to initial weights or feature maps to be applied by the respective neurons or kernels of the signal processing architecture. In this regard, predetermined initial weights or feature maps may be used, such as random distributions of initial weights or feature maps. Spoken differently, the signal processing architecture based on artificial intelligence is then not required to be trained from the scratch. Thereby, the number of repetitions required for optimizing the parameters of the signal processing architecture based on artificial intelligence can be reduced.

According to another example, in case of a gradient-based optimization scheme, the gradient descent to prevent overfitting of the signal processing architecture may be regularized by applying predetermined models. For example, models such as “L1 regularization” (Lasso regression), “L2 regularization” (ridge regression), “max norm constraints”, or “dropout” may be applied in this regard.

Using L1 regularization, a number of available parameters (weights) is shrunk towards 0. This leads to the fact, that specific features are obsolete and neglected during the training.

L2 regularization refers to an approach, where a portion of the available parameters (weights) is modified to become small, but not exactly 0. This causes the respective weights to have reduced influences but not to be negligible. In essence, the influence of different parameters (weights), which are not modified, is enhanced.

In effect, whereas L1 regularization penalizes the sum of absolute values of the weights, L2 regularization penalizes the sum of squares of the weights. The L1 regularization solution is sparse. The L2 regularization solution is non-sparse. The L2 regularization doesn't perform a feature selection, since weights are only reduced to values near 0 instead of truly being 0. Put differently, in contrast to L2 regularization, L1 regularization has a built-in feature selection.

The max norm constraint model refers to a regularization for enforcing an absolute upper bound on the magnitude of the weight vector for every neuron or kernel. Accordingly, a projected gradient descent is used to enforce the constraint. This model ensures that the underlying signal processing architecture cannot “explode” even if the learning rates are set too high because the updates are always bounded by the constraint.

In case of dropout, certain neurons or kernels of the signal processing architecture are disregarded in a layer at random during the computer-implemented method for training. Put differently, since only a portion of all neurons or kernels of the signal processing architecture is set during a specific training repetition, the selected neurons or kernels are disproportionately improved with regard to their signal processing behavior since they experience enhanced portions of the training procedure.

According to another aspect, the present disclosure also relates to a data processing device comprising means (e.g., circuitry) for carrying out the computer-implemented method for training a signal processing architecture based on artificial intelligence to at least partially compensate non-ideal characteristics of electrical signals as described herein before. The advantages achieved in view of the before mentioned computer-implemented method for training are correspondingly achieved also in view of the data processing device.

According to another aspect, the present disclosure also relates to a computer program product comprising instructions which, when the program is executed by a computer or other computing device, cause the computer or other computing device to carry out the computer-implemented method for training a signal processing architecture based on artificial intelligence as described before. The advantages achieved in view of the before mentioned computer-implemented method for training are correspondingly achieved also in view of the computer program product.

According to another aspect, the present disclosure also relates to a computer-readable storage medium comprising instructions which, when executed by a computer or other computing device, cause the computer or other computing device to carry out the computer-implemented method for training a signal processing architecture based on artificial intelligence as described before. The advantages achieved in view of the before mentioned computer-implemented method for training are correspondingly achieved also in view of the computer-readable storage medium.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 is a schematic drawing of a test and/or measurement instrument according to an embodiment;

FIG. 2 is a schematic illustration of a method for processing an electrical signal according to an embodiment; and

FIG. 3 is a schematic illustration of a computer-implemented method for training a signal processing architecture based on artificial intelligence to at least partially compensate non-ideal characteristics of electrical signals according to an embodiment.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

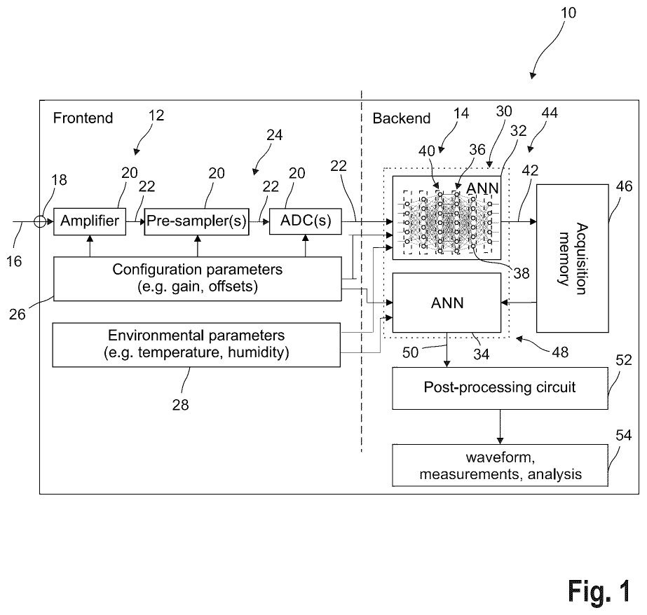

FIG. 1 is a schematic illustration of a test and/or measurement instrument 10 according to an embodiment. As shown in FIG. 1, the test and/or measurement instrument 10 comprises a frontend 12 and a backend 14 being arranged subsequent to the frontend 12.

The test and/or measurement instrument 10 comprises an input 18 of the frontend 12 via which an electrical signal can be received, namely an input signal. For example, the electrical signal 16 may be received from a device under test, DUT.

The frontend 12 comprises several processing circuits 20 that process the electrical signal 16 received. According to the present embodiment, a first processing circuit 20 is an amplifier, a second processing circuit 20 is at least one pre-sampler, and a third processing circuit 20 is an analog-to-digital converter (ADC).

Accordingly, the received electrical signal 16 is amplified depending on a gain of the amplifier, thereby already generating a processed signal 22. The first processing circuit 20, namely the amplifier, may already introduce distortions when processing the electrical signal. Hence, the processed electrical signal provided by the first processing circuit 20 comprises signal distortions, for instance linear or non-linear distortions.

The pre-sampler, namely the second processing circuit 20, is configured to perform a standardization of the electrical signal, for example the processed electrical signal obtained from the first processing circuit 20, thereby also providing a (further) processed electrical signal 22. The pre-sampler may also be set.

The third processing circuit 20, e.g. the ADC, is arranged subsequent to the pre-sampler so as to receive the (further) processed electrical signal from the pre-sampler. Hence, the third processing circuit 20, namely the ADC, is configured to transform the electrical signal received into a digital representation thereof, which also relates to a processed electrical signal 22.

In general, the respective processing circuits 20 of the frontend 12 are optional, for instance the pre-sampler. In addition, the sequence of the processing circuits 20 of the frontend 12 can be varied in other embodiments.

The processing circuits 20 establish a signal path 24 via which the electrical signal 16 received via the input 18 is processed by the frontend 12, namely its components. In other embodiments, the test and/or measurement instrument 10 may comprise several signal paths 24 having separate processing circuits 20. For example, multiple different ADCs may be used and arranged in parallel to enhance the sampling rate and/or bandwidth, for instance interleaved ADCs.

In any case, at least one processed electrical signal 22 is obtained as a result of the processing of the frontend 12 to the electrical signal 16 received via the input 18. The processed electrical signal 22 generally comprises linear as well as non-linear signal distortions caused by the processing circuits 20 of the frontend 12.

The respective signal distortions of the processed electrical signal 22 are influenced by manifold parameters. For example, configuration parameters 26 may be used for setting the test and/or measurement instrument 10, such as gain or offset, wherein the configuration parameters 26 are executed by the respective processing circuits 20 so as to influence the processing routines employed by the processing circuits 20.

In addition, environmental parameters 28, such as temperature or humidity, may also influence the performance of processing circuits 20 of the frontend 12, for example the distortions introduced when processing the electrical signal 16 received via the input 18.

As indicated above, the backend 14 is connected with the frontend 12 such that the processed electrical signal 22 provided by the frontend 12 is forwarded to the backend 14 of the test and/or measurement instrument 10. In the embodiment shown, the backend 14 of the test and/or measurement instruments 10 comprises at least one signal processing architecture 30 based on artificial intelligence, which receives the processed electrical signal 22.

According to the present embodiment, the signal processing architecture 30 based on artificial intelligence comprises a first artificial neural network 32 and a second artificial neural network 34 which are formed separately from each other as shown in FIG. 1. Each artificial neural network 32, 34 comprises at least one layer 36, in general multiple cascaded layers 36 illustrated by the dashed lines, having at least one artificial neuron 38 illustrated by circles. The respective structure is shown in FIG. 1 only for the first artificial neural network 32 for the sake of a better overall overview.

Moreover, each artificial neural network 32, 34 comprises, for example, an input layer receiving an input signal provided to the respective artificial neural network 32, 34, an output layer providing an output signal of the respective artificial neural network 32, 34, and multiple subsequent hidden layers arranged between the input layer and the output layer. Since each artificial neural network 32, 34 comprises multiple subsequent hidden layer, each artificial neural network 32, 34 is configured to employ machine learning techniques and/or deep learning techniques.

In an embodiment, the at least one artificial neural network 32, 34 comprises at least one convolutional layer 40. In other words, at least one of the layers 36 may be a convolutional layer 40. Accordingly, the respective neuron 38 may relate to a kernel, namely a neuron applying a kernel function.

The input layer and the output layer of the artificial neural network 32, 34 are fully-connected layers 36 in a sense that the neurons 38 of these layers 36 are fully-connected neurons 38.

In an embodiment, the signal processing process being employed by each neuron 36, e.g. the kernel function, is described by the respective weight or feature map employed by the respective neuron 36. The weight or feature map can be mathematically explained as a matrix describing the relative probabilities of certain connections within the underlying artificial neural network 32, 34.

In an embodiment, the overall processing applied to the processed electrical signal 22 by the signal processing architecture 30 based on artificial intelligence is characterized by the parameters of the respective structures, namely the artificial neural networks 32, 34. The weights or feature maps are established such that the signal distortions caused by the signal processing circuits 20 of the frontend 12 to the received electrical signal 16 are at least partially compensated by the signal processing architecture 30 based on artificial intelligence 60.

As already indicated above, the test and/or measurement instruments 10 comprises two artificial neural networks 32, 34 within the backend 14, the first artificial neural network 32 provides an at least partially compensated electrical signal 42 as an output signal. For instance, the first artificial neural network 32 is in particular assigned and configured to at least partially compensate the signal distortions caused by the first processing circuit 20 of the frontend 12, namely the amplifier.

Notably, the first artificial neural network 32 is configured to at least partially compensate the signal distortions in real time. That means that the signal distortion compensating procedure is executed at a speed being larger than or at least matching the sampling speed of the frontend 12. In other words, the first artificial neural network 32 is located in a real-time portion 44 of the backend 14.

Subsequently, the at least partially compensated electrical signal 42 is provided to an acquisition memory 46 of the backend 14. Accordingly, the electrical signal received by the acquisition memory 46 can be at least intermediately stored therein for further use, namely post-processing.

In an embodiment, the signal processing architecture 30 based on artificial intelligence also comprises the second artificial neural network 34 receiving electrical signals intermediately stored within the acquisition memory 46. For instance, the second artificial neural network 34 is assigned and set up such that it is configured to compensate for signal distortions caused by the second processing circuit 20 and/or the third processing circuit 20 of the frontend 12, namely the pre-sampler and/or the ADC(s). In this regard, the second artificial neural network 34 differs from the first artificial neural network 32 at least with regard to the weights and feature maps of the underlying neurons 36 or the kernel functions.

Since the second artificial neural network 34 receives intermediately stored electrical signals from the acquisition memory 46, the second artificial neural network 34 is configured to at least partially compensate the respective signal distortions in non-real time. Actually, the second artificial neural network 34 is located in a post-processing portion 48 of the backend 14.

As a consequence, the signal processing architecture 30 based on artificial intelligence provides a (fully) compensated electrical signal 50 for which the signal distortions caused by (all) components of the frontend 12, for instance all processing circuits 20, are compensated, for example fully. Notably, linear as well as non-linear signal distortions may be compensated. In view of non-linear signal distortions, the kernel functions may make use of non-linear signal processing behaviors which is achieved by the respective convolutional layers 40 being trained such that the kernel functions apply a non-linear activation function, such as the sigmoid function, the softmax function, and a rectified linear unit (also called ReLU). This enables non-linear responses to be obtained by each kernel.

In general, the characteristics of the distortion compensating procedure employed by the signal processing architecture 30 based on artificial intelligence may be adapted in view of the respective weights or feature maps of the neurons 36 or kernel functions such that the functionalities of several filter types are mimicked, such as an electrical linear filter, a Volterra filter, or a non-linear filter.

To improve the ability of the signal processing architecture 30 based on artificial intelligence for compensating the signal distortions comprised within the processed electrical signals 22, the configuration parameters 26 and/or environmental parameters 28 may be regarded by the signal processing architecture 30 and its artificial neural networks 32, 34. Accordingly, the quality of the compensated electrical signal 50 is improved as to the distortion compensation.

In an embodiment, the test and/or measurement instruments 10 also comprises a post-processing circuit 52 associated with the post-processing portion 48 of the backend 14, wherein the post-processing circuit 52 receives the (fully) compensated electrical signal 50. The post-processing circuit 52 may be configured to remove a standardization from the compensated electrical signal 50. In an embodiment, the post-processing circuit 52 is configured to compensate the standardization applied by the pre-sampler of the frontend 12.

Although the post-processing circuit 52 is depicted here as a separate circuit, the post-processing circuit 52 may in other embodiments also be part of the signal processing architecture 30 based on artificial intelligence. For example, the compensation of the standardization may be obtained by a portion of an artificial neural network 32, 34, such as a final portion preceding an output layer thereof.

In an embodiment, the backend 14 of the test and/or measurement instrument 10 also comprises an output interface 54, e.g. for displaying a waveform of the respectively obtained (fully) compensated electrical signal for a user of the test and/or measurement instrument 10. Optionally, the output interface 54 can also be applied to provide further insights obtained from the post-processing circuit 52, e.g. measurements and/or analysis.

While the acquisition memory 46 is shown to be arranged between the separately formed artificial neural networks 32, 34, the acquisition memory 46 may in different embodiments also be arranged at different locations, such as before the, i.e. upstream of the signal processing architecture 30 based on artificial intelligence or subsequent to, i.e. downstream of the entire signal processing architecture 30 based on artificial intelligence.

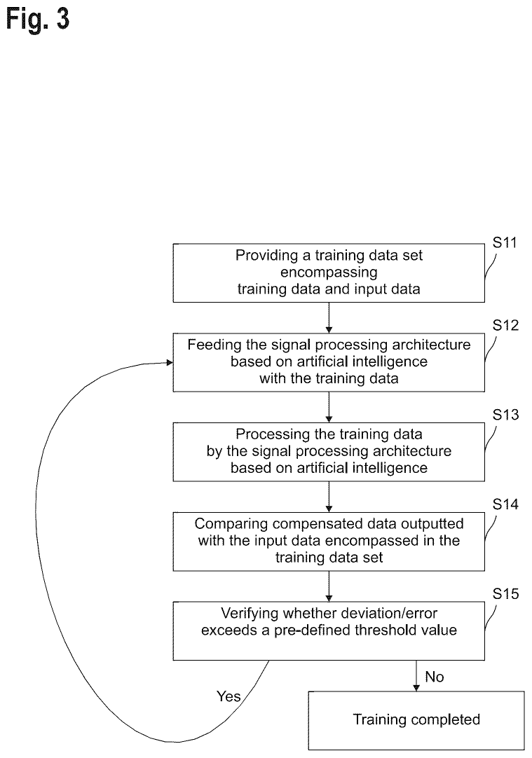

Generally, the signal processing architecture 30 based on artificial intelligence, e.g. the artificial neural networks 32, 34, is trained by a computer-implemented method for training, an example of which is shown in FIG. 3.

FIG. 3 is a schematic illustration of the computer-implemented method for training the signal processing architecture 30 based on artificial intelligence to at least partially compensate distortions of electrical signals introduced by the frontend 12 of the test and/or measurement instrument 10 when processing the electrical signal 16.

According to a first training step S11 of the method, a training data set is provided, which encompasses input data associated with the electrical signal 16 received by the frontend 12 and training data associated with the electrical signal processed 22 by the frontend 12 of the test and/or measurement instrument 10.

In a second training step S12 of the method, the signal processing architecture 30 based on artificial intelligence is fed with the training data encompassed in the training data set.

In a third training step S13 of the method, the processing architecture 30 based on artificial intelligence processes the training data so as to at least partially compensate any distortions comprises in the training data indicative of the electrical signal processed 22 by the frontend 12 of the test and/or measurement instrument 10. The processing architecture 30 based on artificial intelligence outputs compensated data that is associated with an at least partially compensated electrical signal.

In a fourth training step S14 of the method, the compensated data outputted by the processing architecture 30 based on artificial intelligence is compared with the input data so as to identify a deviation/error between the compensated data and the electrical signal 16 inputted to the frontend 12. In other words, it is verified whether the processing architecture 30 based on artificial intelligence is enabled to compensate any distortions introduced by the frontend 12 when processing the electrical signal 16 received. This would be valid in case the compensated data matches the input data.

In a fifth training step S15 of the method, it is verified whether a deviation/error is higher than a pre-defined threshold value.

In case the deviation/error is higher than the pre-defined threshold value, the processing architecture 30 based on artificial intelligence is adapted, e.g. weights, for instance of an underlying artificial neural network structure, and the steps S12 to S15 are repeated as long as the error/deviation is below the pre-defined threshold value, as indicated by the arrow.

In case the deviation/error is not higher than the pre-defined threshold value, the training of the processing architecture 30 based on artificial intelligence is completed. Then, the processing architecture 30 based on artificial intelligence can be used in the test and/or measurement instrument 10 for compensating distortions introduced by the frontend 12 during processing.

Since the signal processing architecture 30 based on artificial intelligence may employ machine learning or deep learning techniques, the adjustments to the parameters, i.e. the weights and feature maps of the neurons 36 and kernel functions, of the signal processing architecture 30 based on artificial intelligence may be achieved in an automated fashion.

In this regard, an optimization scheme may be one of a gradient-based optimization scheme and an error minimization scheme.

For the gradient optimization scheme, a derivative is considered to evaluate the quality of the distortion compensating procedure. The gradient optimization scheme relates to a first-order iterative algorithm for finding a local minimum, namely the local minimum of the deviation/error between the input data and the compensated data.

In case of the error minimization scheme, the adaption of the parameters of the signal processing architecture 30 based on artificial intelligence are based on a mean error determined in view of the difference between the input data associated with several input signals and the compensated data.

Generally, the training data set used for training the signal processing architecture 30 based on artificial intelligence can be obtained from a series of measurements and/or from simulations. In an embodiment, the training data may relate to measured data.

In any case, the signal processing architecture 30 based on artificial intelligence of the test and/or measurement instrument 10 shown in FIG. 1 may be trained according to the method shown in FIG. 3 such that the test and/or measurement instrument 10 comprises a trained artificial intelligence. In other words, the test and/or measurement instrument 10 comprises the signal processing architecture 30 based on trained artificial intelligence.

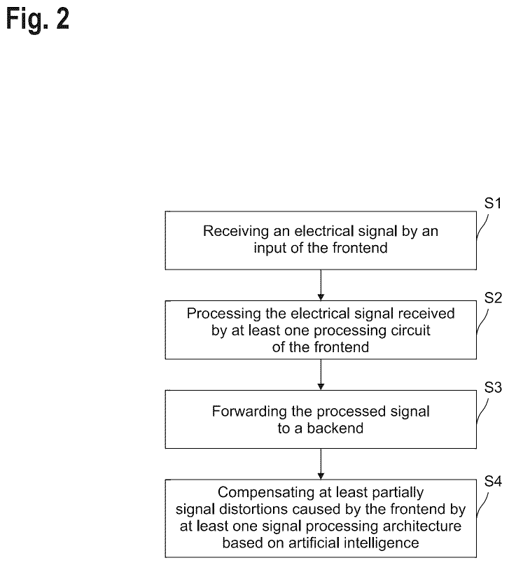

The test and/or measurement instrument 10 is generally enabled to perform the method for processing an electrical signal 16, an example of which is shown in FIG. 2.

In a first step S1, the electrical signal 16 is received by the input 18 of the frontend 12 of the test and/or measurement instrument 10.

In a second step S2, the electrical signal 16 is processed by at least one of the processing circuits 20, thereby providing the processed electrical signal 22 that however comprises distortions introduced by the at least one processing circuit 20.

In a third step S3, the processed electrical signal 22 is forwarded to the backend 14 that comprises the signal processing architecture 30 based on artificial intelligence, the acquisition memory 46 as well as the post-processing circuit 52. As already discussed with respect to the embodiment shown in FIG. 1, the signal processing architecture 30 based on artificial intelligence may comprise one or several artificial neural network(s) 32, 34 for processing the processed electrical signal 22.

In a fourth step S4, the processed electrical signal 22 is processed in the backend 14 by the signal processing architecture 30 based on the trained artificial intelligence so as to at least partially compensate the signal distortions caused by the frontend 12 when processing the electrical signal 16.

Consequently, the signal processing architecture 30 based on the trained artificial intelligence is enabled to output an output signal without any distortions introduced by the frontend 12, namely a compensated signal. The compensated signal may be acquired in the acquisition memory 46, processed further by the post-processing circuit 52, and/or directly outputted via the output interface 54.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components, such as the frontend 12 and the backend 14, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuitry to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A test and/or measurement instrument for analyzing an electrical signal, wherein the test and/or measurement instrument comprises a frontend having at least an input for receiving an electrical signal, wherein the frontend also comprises at least one processing circuit configured for processing the electrical signal, thereby generating a processed electrical signal,
wherein the test and/or measurement instrument also comprises a backend connected with the frontend such that the backend receives the processed electrical signal, wherein the backend comprises at least one signal processing architecture based on artificial intelligence, wherein the signal processing architecture based on artificial intelligence is configured for at least partially compensating signal distortions caused by the frontend when processing the electrical signal in order to generate the processed electrical signal.

2. The test and/or measurement instrument of claim 1, wherein the signal processing architecture based on artificial intelligence is based on machine learning or deep learning.

3. The test and/or measurement instrument of claim 1, wherein the signal processing architecture based on artificial intelligence comprises an artificial neural network.

4. The test and/or measurement instrument of claim 1, wherein the signal processing architecture based on artificial intelligence comprises at least one layer.

5. The test and/or measurement instrument of claim 1, wherein the signal processing architecture based on artificial intelligence is configured to convolute the processed electrical signal with at least one kernel and to provide an output signal.

6. The test and/or measurement instrument of claim 1, wherein the signal processing architecture based on artificial intelligence comprises at least two cascaded layers, wherein one of the cascaded layers is an output layer that outputs an output signal with at least partially compensated signal distortions.

7. The test and/or measurement instrument of claim 1, wherein the at least one signal processing architecture based on artificial intelligence is configured to at least compensate linear and/or non-linear signal distortions caused by the frontend.

8. The test and/or measurement instrument of claim 1, wherein the at least one processing circuit is configured to perform a standardization of the electrical signal.

9. The test and/or measurement instrument of claim 1, wherein the test and/or measurement instrument comprises a post-processing circuit configured to remove a standardization from the output signal.

10. The test and/or measurement instrument of claim 9, wherein the post-processing circuit is arranged downstream of the at least one signal processing architecture based on artificial intelligence, or wherein the post-processing circuit is established by a final portion of the at least one signal processing architecture based on artificial intelligence, preceding an output layer of the at least one signal processing architecture based on artificial intelligence.

11. The test and/or measurement instrument of claim 1, wherein the at least one signal processing architecture based on artificial intelligence is configured to at least partially compensate signal distortions introduced by the frontend in real-time.

12. The test and/or measurement instrument of claim 1, wherein the test and/or measurement instrument comprises an acquisition memory for storing at least partially compensated electrical signals, and wherein the acquisition memory is arranged downstream of the at least one signal processing architecture based on artificial intelligence.

13. The test and/or measurement instrument of claim 1, wherein the test and/or measurement instrument comprises an acquisition memory for storing processed electrical signals, and for providing the processed electrical signals to the at least one signal processing architecture based on artificial intelligence, wherein the acquisition memory is arranged upstream of the at least one signal processing architecture based on artificial intelligence, and wherein the at least one signal processing architecture based on artificial intelligence is configured to at least partially compensate signal distortions in non-real-time based on the received processed electrical signals.

14. The test and/or measurement instrument of claim 1, wherein the at least one signal processing architecture based on artificial intelligence is coupled to or comprises at least one of an electrical linear filter, a Volterra filter, or a non-linear filter.

15. The test and/or measurement instrument of claim 1, wherein the test and/or measurement instrument comprises two signal paths for processing electrical signals, which are provided outside the signal processing architecture based on artificial intelligence.

16. The test and/or measurement instrument of claim 1, wherein the at least one signal processing architecture based on artificial intelligence is configured to take at least one configuration parameter and/or at least one environmental parameter of the frontend into account, wherein the at least one configuration parameter and/or at least one environmental parameter influences the distortions caused by the frontend during processing the electrical signal.

17. A method for processing an electrical signal, the method comprising at least the steps of:
receiving an electrical signal by at least one input of a frontend of a test and/or measurement instrument,
processing the electrical signal by at least one processing circuit of the frontend, thereby generating a processed electrical signal,
forwarding the processed electrical signal to a backend of the test and/or measurement instrument, and
compensating at least partially distortions caused by the frontend during processing of the electrical signal by at least one signal processing architecture based on artificial intelligence.

18. A computer-implemented method for training a signal processing architecture based on artificial intelligence to at least partially compensate distortions of electrical signals introduced by a frontend of a test and/or measurement instrument, wherein the signal processing architecture based on artificial intelligence is trained by a training data set such that the signal processing architecture based on artificial intelligence is configured to at least partially compensate the distortions introduced by the frontend of the test and/or measurement instrument when processing the electrical signal, wherein the training data set encompasses input data associated with the electrical signal received by the frontend and training data associated with an electrical signal processed by the frontend of the test and/or measurement instrument, wherein the signal processing architecture based on artificial intelligence is fed with the training data such that the signal processing architecture based on artificial intelligence processes the training data in order to output compensated data associated with an at least partially compensated electrical signal, wherein the compensated data is compared with the input data encompassed in the training data set in order to determine a deviation between the input data and the compensated data outputted by the signal processing architecture based on artificial intelligence, and wherein the signal processing architecture based on artificial intelligence is adapted when a deviation between the input data and the compensated data occurs that is higher than a pre-defined threshold value.

19. The computer-implemented method of claim 18, wherein at least one of a gradient-based optimization scheme and an error minimization scheme is applied when comparing the compensated data outputted by the signal processing architecture based on artificial intelligence with the input data encompassed in the training data set.

20. The computer-implemented method of claim 18, wherein the training data set is obtained from a series of measurements and/or from simulations.
